(19) United States
(12) Patent Application Publication
(10) Pub. No.: US 2001/0023951 A1
(43) Pub. Date: Sep. 27, 2001

(54) Method of manufacturing a ferroelectric capacitor

(76) Inventors: June-key Lee, Suwon-city (KR); Bon-jae Koo, Suwon-city (KR)

Correspondence Address: The Law Offices of Eugene M Lee, PLLC, Suite 1200, 2111 Wilson Boulevard, Arlington, VA, 22201, US

(21) Appl. No.: 09/816,216

(22) Filed: Mar. 26, 2001

(30) Foreign Application Priority Data
Mar. 24, 2000 (KR) 00-15033
Dec. 29, 2000 (KR) 00-86285

(51) Int. Cl. H04L 12/28; H01L 21/00; H01L 29/76; H01L 29/94; H01L 31/062; H01L 31/113; H01L 31/119; H04L 12/56; H04J 3/26

(52) U.S. Cl. 257/295; 370/390; 370/392; 370/432; 438/3

(57) ABSTRACT

A method of manufacturing a ferroelectric capacitor includes the steps of forming a lower electrode on a substrate, forming a ferroelectric layer on the lower electrode, forming an upper electrode on the ferroelectric layer, forming a wiring layer on the upper electrode, and applying a voltage to an electrode selected from the upper electrode and the lower electrode, the voltage being greater than the operational voltage of the electrode, to regularly align an electric dipole of the ferroelectric layer.

### BACKGROUND OF THE INVENTION

1. Field of the Invention

The present invention relates to a method of manufacturing a ferroelectric capacitor), and more particularly, to a method of manufacturing a ferroelectric capacitor by which degradation of PZT (PbZrₓTi₁₋ₓO₃) or SBT (SrBi₂Ta₂O₉) thin films due to hydrogen can be minimized during a manufacturing process.

2. Description of the Related Art

PZT is a material in which La, Sr, Ca, Sc, Nb, Ta, Ni, Fe, or Er is added to Pb(ZrₓTi₁₋ₓ)O₃. PZT is characterized in that electric dipoles will align in the direction of an electric field depending on an applied voltage, and they will remain aligned after the voltage is removed, thus eliminating the need to be electrically refreshed. This type of PZT thin film is applied to a ferroelectric random access memory (FRAM) as a memory device. Unlike a dynamic random access memory (DRAM), a FRAM whose capacitor is manufactured with a PZT thin film does not need to be refreshed. Furthermore, the FRAM can offer higher integration density and higher operation speeds than a static random access memory, an electrically erasable programmable read only memory (EEPROM), or a flash memory can.

FIG. 1 is a schematic cross-sectional view of a PZT capacitor adopted in a general FRAM. Referring to FIG. 1, a lower electrode 2 is formed on a silicon substrate 1, on top of which a PZT layer 3 and an upper electrode 4 are sequentially formed. A metallization layer 5 of Al is formed on a contact portion 5a on the top center portion of the upper electrode 4. Furthermore, a barrier layer 6 of TiO₂ or Al₂O₃ is formed on two sides of the PZT layer 3 and a portion other than the contact portion 5a of the upper electrode 4, on top of which an inter-metal dielectric (IMD) silicon oxide layer 7 is formed. A passivation layer 8 and a plastic package layer 9 are provided thereon.

During the manufacture of the FRAM, the ferroelectric PZT thin film is exposed to hydrogen atoms and degraded after undergoing several kinds of processes such as dry etching, silicon oxide deposition, forming gas anneal (FGA), and plastic packaging. To prevent degradation of a PZT thin film due to hydrogen, the barrier layer 6 of TiO₂ or Al₂O₃ overlies the entire PZT layer 3 except for the contact portion 5a, which does not completely prevent this degradation. To recover from degradation of the PZT during a manufacturing process, a conventional manufacturing method involves recovery annealing under a high temperature.

However, in the conventional method, it is difficult to perform recovery annealing at a temperature higher than the melting point of Al due to the low Al melting point (670° C.) after forming the metallization layer 5 of Al. Furthermore, as shown in FIG. 1, in manufacturing a FRAM, the degradation of PZT occurs due to hydrogen also during a process of forming a passivation layer using SiO₂ and a plastic package process after forming the metallization layers of Al. In this case, as described above, annealing cannot be performed due to the low Al melting point.

Thus, a conventional FRAM has problems of low performance and short lifetime since it is not been manufactured using a complete means for preventing degradation of a PZT thin film.

### SUMMARY OF THE INVENTION

It is a feature of the present invention to provide a method of manufacturing a ferroelectric capacitor capable of effectively minimizing degradation of a ferroelectric layer due to hydrogen.

It is another feature of the invention to provide a method of manufacturing a ferroelectric capacitor using a ferroelectric layer capable of offering high performance and prolonged lifetime.

In accordance with one aspect of the present invention, there is provided a method of manufacturing a ferroelectric capacitor including the steps of forming a lower electrode on a substrate, forming a ferroelectric layer on the lower electrode, forming an upper electrode on the ferroelectric layer, forming a wiring layer on the upper electrode, and applying a voltage to an electrode selected from the upper electrode and the lower electrode, the voltage being greater than the operational voltage of the electrode, to regularly align an electric dipole of the ferroelectric layer.

Preferably, the ferroelectric layer is formed of at least one PZT (PbZrₓTi₁₋ₓO₃) family ferroelectric material or at least one SBT (SrBi₂Ta₂O₉) family ferroelectric material. If the ferroelectric layer is formed of at least one SBT family ferroelectric material, at least one of Nb, Ti, and Ca is added to the SBT family material(s).

In more specific embodiments, the upper and lower electrodes are formed of platinum, and a positive voltage is applied to the upper electrode or a negative voltage is applied to the lower electrode. In additional more specific embodiments, the upper and lower electrodes have stacked structures of Ir/IrO₂ and Pt/IrO₂, respectively, and a negative voltage is applied to the upper electrode or a positive voltage is applied to the lower electrode.

Ferroelectric capacitors produced according to the inventive methods are also provided.

### BRIEF DESCRIPTION OF THE DRAWINGS

The above and other features and advantages of the present invention will become more apparent by describing in detail a preferred embodiment thereof with reference to the attached drawings in which:

FIG. 1 is a schematic cross-sectional view of a general ferroelectric capacitor using PZT (PbZrₓTi₁₋ₓO₃);

FIGS. 2-10 are cross-sectional views showing a method of manufacturing a ferroelectric capacitor according to an embodiment of the invention;

FIGS. 11-12 shows polarization states that are produced in different directions on a PZT layer in a method of manufacturing a ferroelectric capacitor according to an embodiment of the invention;

FIG. 13 includes graphs showing changes in polarization of the PZT when polarization has been produced on the PZT layer as shown in FIGS. 11 and 12 according to the invention; and

FIG. 14 shows the state in which polarization is produced in a ferroelectric layer having a stacked structure of Ir/IrO₂/PZT/Pt/IrO₂, in accordance with another embodiment of the invention.

### DETAILED DESCRIPTION OF THE INVENTION

Priority Korean Patent Application No. 00-15033, filed Mar. 24, 2000, is incorporated herein in its entirety by reference.

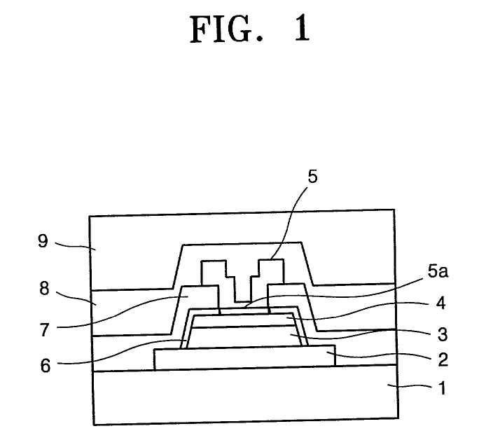

A method of manufacturing a ferroelectric capacitor according to the invention is the same as the conventional method up to the step of forming the metal writing layer (5 of FIG. 1). Then, a voltage of a polarity given to the upper electrode 4 or the lower electrode 2 is applied to regularly align dipoles in a ferroelectric layer 3, before performing a passivation process. According to the present invention, the ferroelectric layer 3 may be formed of PZT family ferroelectric materials or SBT (SrBi₂Ta₂O₉) family ferroelectric materials.

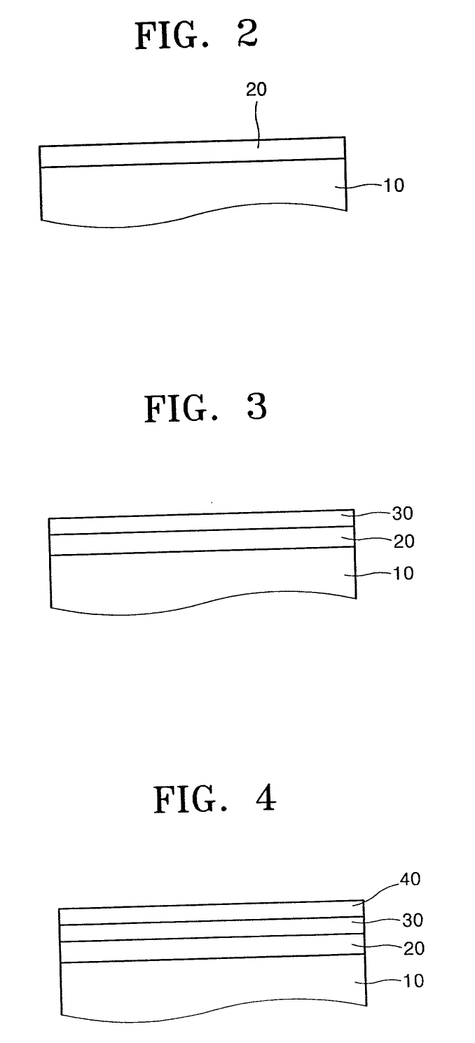

First, a method of manufacturing a ferroelectric capacitor of a Pt/PZT/Pt structure according to an embodiment of the invention will now be described. Referring to FIG. 2, a lower electrode 20 is formed over a silicon substrate 10. Here, the lower electrode 20 preferably is formed of a Pt film by using a DC magnetron sputtering technique. In this case, since a transistor is generally positioned in a lower portion of the capacitor in a FRAM, a silicon oxide (SiO₂) insulating layer underlies the Pt lower electrode 20 for insulation from the transistor. In other words, the Pt lower electrode 20 is formed on top of the SiO₂ insulating layer. Additionally, in a real FRAM structure, an adhesive layer may be interposed between the SiO₂ insulating layer and the lower electrode 20 in order to improve the adhesive property of the lower electrode 20.

As shown in FIG. 3, a PZT layer 30 is formed on the lower electrode 20. The PZT layer 30 can be formed, for example, by a sol-gel method. Specifically, after spin coating a PZT solution to a thickness of about 250 nm, a heat treatment is performed on the PZT solution at about 650° C. for thirty minutes to harden it. Then, the hardened PZT is etched, preferably by dry etching using a photo mask to obtain the PZT layer 30 having a desired pattern.

Referring to FIG. 4, a Pt upper electrode 40 is formed on top of the PZT layer 30, preferably using the same method used in forming the lower electrode 20. Thereafter, the Pt upper electrode 40 is patterned, preferably by dry etching using a photo mask.

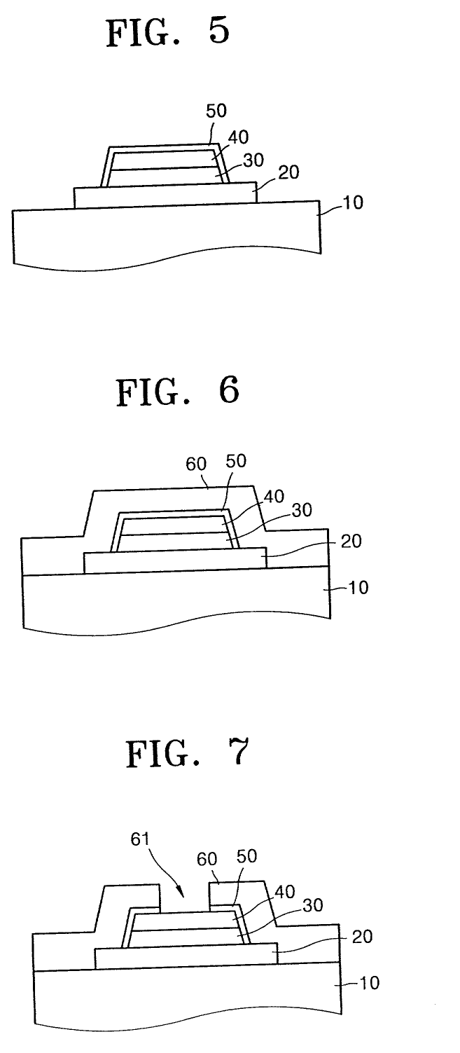

As seen in FIG. 5, a barrier layer 50 comprised, for example, of TiO₂, is formed along a crosswise portion and on top of the patterned upper electrode 40, preferably using chemical vapor deposition (CVD) or sputtering.

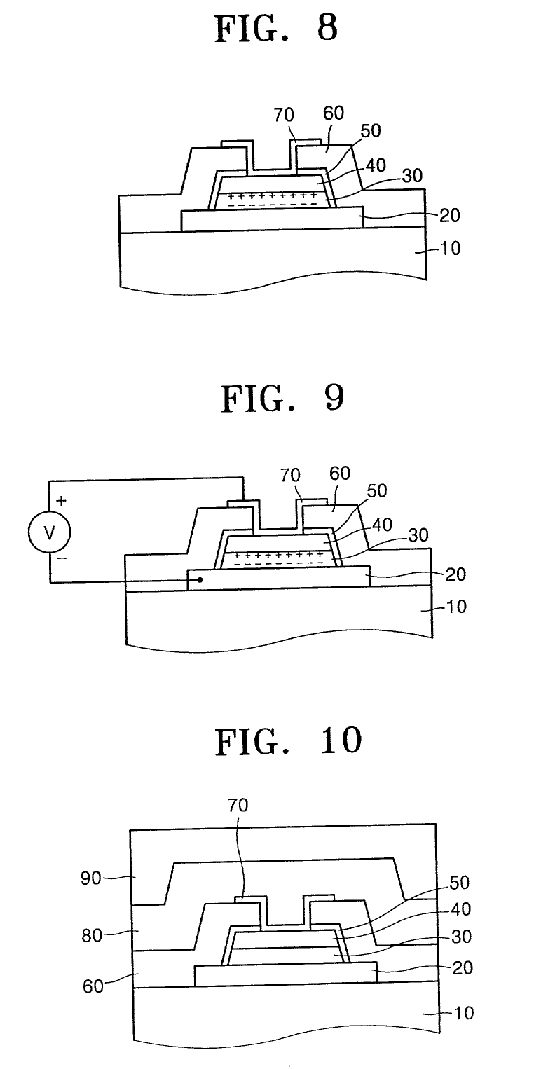

As shown in FIG. 6, an inter-metal dielectric (IMD) layer 60, comprised, for example, of SiO₂, is formed on the stacked structure, preferably by CVD. Referring to FIG. 7, a contact hole 61 is formed on the upper electrode 40. In this case, the contact hole 61 is continuously formed in the barrier layer 50 and the IMD layer 60. Thus, the surface of the upper electrode 40 is exposed to the bottom of the contact hole 61. Referring to FIG. 8, a metallization layer 70, preferably made of Al, is formed, for example by sputtering and electron beam deposition.

After undergoing the above processes, as shown in FIG. 9, a voltage is applied to the PZT layer 30 at a predetermined potential through the metallization layer 70 and the lower electrode 20 to generate polarity (+, −) on the PZT layer 30. In this case, a positive voltage is applied to the upper electrode 40, while a negative voltage is applied to the lower electrode 20. The voltage must be greater than the operational voltage of the PZT layer 30. In this embodiment, a polarization voltage applied to the PZT layer 30 is set at 5 V. One feature of the invention lies in this process, since this process minimizes degradation of the PZT layer 30 due to hydrogen generated during a subsequent process.

Referring to FIG. 10, a passivation layer 80 is formed, preferably of silicon oxide or silicon nitride, on the metallization layer 70, for example by means of CVD, on top of which a plastic package layer 90 is formed.

Although patterning processes for the lower electrode 20, the PZT layer 30, and the upper electrode 40 are performed separately in this embodiment, it is only an example. Thus, the lower electrode 20, the PZT layer 30, and the upper electrode 40 can be patterned together by means of dry etching after providing a mask thereon.

The present invention prevents degradation of the PZT layer 30 due to hydrogen generated during a manufacturing process of the PZT capacitor. Hydrogen generated during the process has a tendency to collect at the interface of the capacitor (upper electrode/PZT/lower electrode). In a commonly used Pt/PZT/Pt capacitor, hydrogen collects at the interface between the upper electrode and the PZT, and thus collecting hydrogen degrades the characteristics of the PZT capacitor. To compensate for degradation of the PZT layer 30, the present invention involves application of a positive voltage to the upper electrode 40, as shown in FIG. 9, after forming the metallization layer 70.

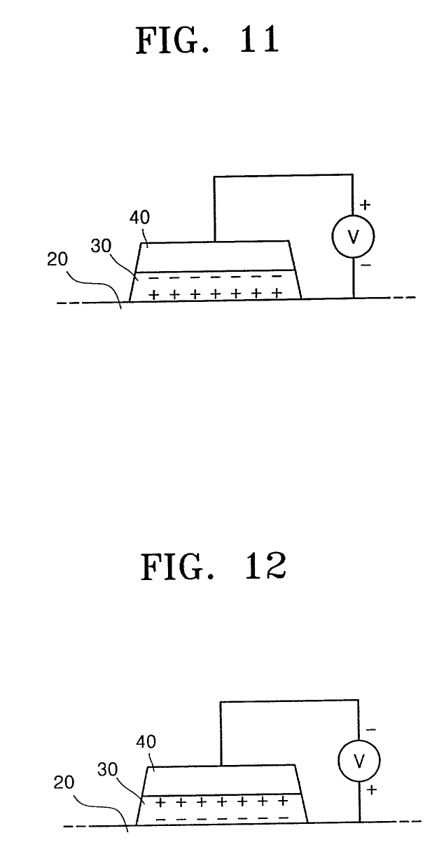

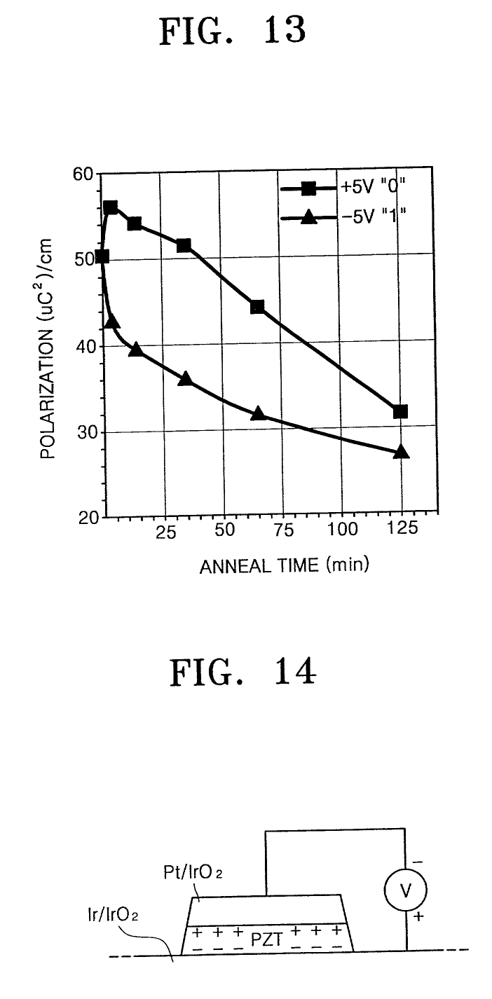

FIG. 11 shows the polarization state of the PZT layer 30 when a positive voltage is applied to the upper electrode 40, and FIG. 12 shows the polarization state of the PZT layer 30 when a negative voltage is applied to the upper electrode 40. Graphs of the polarization versus annealing time for the embodiments of FIGS. 11 and 12 are shown in FIG. 13.

The results of producing the two polarization states on the PZT layer 30 show that application of a positive voltage (e.g., +5 V) to the upper electrode 40 is resistant to hydrogen degradation compared to the opposite case. This is because most hydrogen atoms collect at the interface between the upper electrode 40 and the PZT layer 30, and a negative dipole at the PZT interface hinders the approach of the hydrogen.

Meanwhile, in the case where a capacitor has a stacked structure of Ir/IrO₂/PZT/Pt/IrO₂ instead of a Pt/PZT/Pt structure, as shown in FIG. 14, most hydrogen atoms collect at the interface between the lower electrode 20 and the PZT layer 30. In this case, application of a positive voltage to the lower electrode 20 produces a negative dipole at the interface between the PZT layer 30 and the lower electrode 20, which thereby minimizes hydrogen degradation of the PZT layer 30.

To compensate for degradation of the PZT layer 30 due to hydrogen, a negative dipole is produced at a region where hydrogen is concentrated, in the interface between the PZT layer 30 and the upper electrode 40 or the lower electrode 20, by application of a voltage greater than the operational voltage.

As described in the foregoing, following a process of forming the metallization layer 70, a voltage of, e.g., 3.3 V is applied to the upper and lower electrodes 40 and 20 in the capacitor (Ir/IrO₂(upper electrode)/PZT/Pt/IrO₂(lower electrode)) of a 4.0 Megabit ferroelectric memory, and then after forming the SiO₂ passivation layer 80, plastic packaging is prepared. As a result, application to the upper electrode 40 reduces the integration density by 500 Kilobits, while application to the lower electrode 20 maintains the integration density of 4.0 Megabit.

According to another embodiment of the present invention, the ferroelectric layer can be formed of at least one SBT family ferroelectric material. In this case, the SBT family ferroelectric material(s) preferably include at least one of Nb, Ti, and Ca.

A manufacturing method according to the invention is capable of effectively minimizing degradation of a ferroelectric layer such as a PZT or an SBT film due to hydrogen generated during the manufacturing process, which thereby improves the characteristics of the capacitor while lengthening its life time.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A method of manufacturing a ferroelectric capacitor, the method comprising the steps of:
forming a lower electrode on a substrate;
forming a ferroelectric layer on the lower electrode;
forming an upper electrode on the ferroelectric layer;
forming a wiring layer on the upper electrode; and
applying a voltage to an electrode selected from the upper electrode and the lower electrode, the voltage being greater than the operational voltage of the electrode, to regularly align an electric dipole of the ferroelectric layer.

2. The method of claim 1, wherein the ferroelectric layer is formed of at least one PZT (PbZrₓTi₁₋ₓO₃) family ferroelectric material or at least one SBT (SrBi₂Ta₂O₉) family ferroelectric material.

3. The method of claim 1, wherein the at least one SBT family ferroelectric material includes at least one selected from the group consisting of Nb, Ti, and Ca.

4. The method of claim 1, wherein the upper and lower electrodes are formed of platinum, and a positive voltage is applied to the upper electrode.

5. The method of claim 1, wherein the upper and lower electrodes are formed of platinum, and a negative voltage is applied to the lower electrode.

6. The method of claim 1, wherein the upper and lower electrodes have stacked structures of Ir/IrO₂ and Pt/IrO₂, respectively, and a negative voltage is applied to the upper electrode.

7. The method of claim 1, wherein the upper and lower electrodes have stacked structures of Ir/IrO₂ and Pt/IrO₂, respectively, and a positive voltage is applied to the lower electrode.

8. A ferroelectric capacitor produced by the method of claim 1.

9. A ferroelectric capacitor produced by the method of claim 2.

10. A ferroelectric capacitor produced by the method of claim 3.

11. A ferroelectric capacitor produced by the method of claim 4.

12. A ferroelectric capacitor produced by the method of claim 5.

13. A ferroelectric capacitor produced by the method of claim 6.

14. A ferroelectric capacitor produced by the method of claim 7.
